(19) United States
(12) Patent Application Publication
(10) Pub. No.: US 2023/0213561 A1
(43) Pub. Date: Jul. 6, 2023

(54) Magnetic Field Sensor Assembly, Which is Evenly Distributed Around the Circumference, for Measuring a Magnetic Field of a Conductor of an Electric Current

(71) Applicant: Siemens Aktiengesellschaft, München (DE)

(72) Inventors: Roland Weiss, Erlangen (DE); Florian Zapf, Buckenhof, Bayer (DE); Karl Fleisch, Erlangen (DE)

(73) Assignee: Siemens Aktiengesellschaft, München (DE)

(21) Appl. No.: 17/927,986

(22) PCT Filed: May 6, 2021
(86) PCT No.: PCT/EP2021/061935

§ 371 Date: Nov. 28, 2022

(30) Foreign Application Priority Data
May 26, 2020 (DE) 10 2020 206 528.4

(51) Int. Cl. G01R 21/08; G01R 33/00

(52) U.S. Cl. CPC G01R 21/08; G01R 33/0005

(57) ABSTRACT

Various embodiments of the teachings herein include an apparatus for measuring a magnetic field of a conductor of an electric current. The apparatus may include three magnetic field sensors arranged on a circumference of a non-circular ellipse. The three magnetic field sensors are arranged equidistantly along the circumference of the ellipse. The magnetic field is measured without using a flux concentrator.

### CROSS-REFERENCE TO RELATED APPLICATIONS

This application is a U.S. National Stage Application of International Application No. PCT/EP2021/061935 filed May 6, 2021, which designates the United States of America, and claims priority to DE Application No. 10 2020 206 528.4 filed May 26, 2020, the contents of which are hereby incorporated by reference in their entirety.

### TECHNICAL FIELD

The present disclosure relates to electrical components. Various embodiments of the teachings herein may include apparatus for measuring a magnetic field of a conductor of an electric current, current intensity determination units, and/or methods for determining the electric current intensity in the electric conductor.

### BACKGROUND

Shunt resistors, toroidal core transformers, in particular compensation current transformers, Rogowski coils or individual field probes, in particular a Hall probe or a GMR sensor, are currently used to measure electric currents in electric conductors. In order to measure the electric current without a flux concentrator by means of magnetic field sensors, both “open-loop” and “closed-loop” operation of individual magnetic field sensors is possible, in principle. First transformers which operate without a flux concentrator are intended, in particular, for round conductors. The present measurement methods have the disadvantage of high sensitivity to conductor geometries with a rectangular cross section and different widths of the conductor.

Conductors with a rectangular cross section and sometimes very pronounced aspect ratios occur very often in practice.

Arrangements in which the magnetic field around a conductor is measured using a plurality of field probes and an attempt is made to reduce the extraneous field sensitivity by offsetting the individual signals are already known (for example EP2437072 or DE102009054892). It has often been assumed in this case that the magnetic field of the individual conductor is cylinder-symmetrical with respect to the longitudinal axis of the individual conductor. However, this prerequisite is satisfied only in the case of a cylinder-symmetrical geometry of the conductor or at a relatively large distance from the conductor.

In many technical installations, the geometry of the conductor differs greatly from a cylindrical shape, in particular in conductors which are intended to carry relatively high currents. Flat conductors with a rectangular cross section are often used, for example, in busbars in converters since this conductor shape has, on the one hand, a lower inductance per unit length and therefore a lower impedance for the same cross-sectional area and, on the other hand, enables a lower heat transfer resistance to the environment owing to the larger surface area. In addition, it is possible to manufacture the flat conductor in a cost-effective manner by means of punching and bending from a flat semi-finished product. The material thickness is predefined by the semi-finished product and is limited by the maximum power of the punching and bending machines used. The different cross sections for achieving the necessary current-carrying capacities are set using the width of the bar manufactured.

The shape of the flat conductor results in a distribution of the magnetic field, which differs from the cylindrical symmetry, and requires a current transformer with a relatively large design if the current transformer is circular. Since busbars of different widths are used in different converters, a sensor assembly which correctly measures the current irrespective of the conductor width is particularly advantageous. On account of the manufacturing tolerances for the magnetic field sensors and the tolerances for further electronic components, it is always necessary to compare the current sensors, for example at the end of manufacturing. If a conductor with a geometry differing from the conductor at the place of use can be used for the comparison, this is highly advantageous because a comparison which is “valid” only for specific busbar shapes is associated with great logistical disadvantages, in particular busbar-specific storage. However, a sensor assembly which makes it possible to measure the electric current in a manner largely independent of the shape of the conductor is required for this purpose.

### SUMMARY

The teachings of the present disclosure provide an alternative solution for measuring electric currents in electric conductors without using a flux concentrator. As an example, some embodiments of the teachings herein include an apparatus (8) for measuring a magnetic field of a conductor (1) of an electric current, wherein the magnetic field is measured without using a flux concentrator, having: at least three magnetic field sensors (2), wherein the at least three magnetic field sensors (2) are arranged on a circumference of an ellipse (4), wherein the ellipse (4) is not a circle, wherein the at least three magnetic field sensors (2) are arranged equidistantly along the circumference of the ellipse (4).

In some embodiments, the ellipse (4) has a longest half-axis (a), the longest half-axis (a) meets the ellipse (4) at an ellipse apex (6), one of the at least three magnetic field sensors (2) is arranged at an axial spacing (A) from the ellipse apex (6), and the axial spacing (A) is optimized to minimize a deviation of a result of the measurement of the magnetic field of the conductor (1) of the electric current from a real value of the magnetic field of the conductor (1) of the electric current.

In some embodiments, the ellipse (4) has a longest half-axis (a), the longest half-axis (a) meets the ellipse (4) at an ellipse apex (6), one of the at least three magnetic field sensors (2) is arranged at an axial spacing (A) from the ellipse apex (6), wherein a sensor spacing is defined by the circumference of the ellipse (4) divided by a number (N) of the at least three magnetic field sensors (2), and the axial spacing (A): is an eighth of the sensor spacing in the case of an odd number (N) of the at least three magnetic field sensors (2) and is a quarter of the sensor spacing in the case of an even number (N) of the at least three magnetic field sensors (2).

In some embodiments, the ellipse (4) has a shortest half-axis, and the longest half-axis (a) does not exceed four times the length of the shortest half-axis.

In some embodiments, the at least three magnetic field sensors (2) each have a sensitivity axis (3), the at least three magnetic field sensors (2) have the maximum sensitivity to a magnetic field oriented in the direction of the sensitivity axis (3), and the sensitivity axis (3) is oriented tangentially with respect to the ellipse (4).

In some embodiments, there is an odd number (N) of the at least three magnetic field sensors (2).

In some embodiments, the apparatus (8) is designed to at least partially comprise the conductor (1) of the electric current.

As another example, some embodiments include a current intensity determination unit (9) for determining an electric current intensity in a conductor (1) of an electric current, having: an apparatus (8) as described herein, and a data processing unit (5), wherein the data processing unit (5) is designed to determine the electric current intensity using measurement results from the at least three magnetic field sensors (2).

As another example, some embodiments include a method for determining an electric current intensity in a conductor (1) of an electric current by means of a current intensity determination unit (9) as described herein, having the steps of: placing the conductor (1) of the electric current in an apparatus (8) as described herein, determining measurement results of a magnetic field strength of the magnetic field by means of the apparatus (8), transmitting the measurement results to the data processing unit (5), and determining the electric current intensity in the conductor (1) of the electric current by means of the data processing unit (5).

### BRIEF DESCRIPTION OF THE DRAWINGS

Various features and advantages of the teachings herein become clear from the following explanations of a plurality of exemplary embodiments on the basis of the schematic drawings, in which:

FIG. 1 shows magnetic field sensors arranged equidistantly along the circumference of an ellipse incorporating teachings of the present disclosure;

FIG. 2 shows magnetic field sensors arranged at an axial spacing from the ellipse apex incorporating teachings of the present disclosure;

FIG. 3 shows experimentally determined measurement errors when the conductor geometry is changed incorporating teachings of the present disclosure;

FIG. 4 shows experimentally determined measurement errors when the half-axis ratio is changed incorporating teachings of the present disclosure;

FIG. 5 shows experimentally determined measurement errors in the case of an odd and an even number of magnetic field sensors incorporating teachings of the present disclosure; and

FIG. 6 shows a current intensity determination unit for determining an electric current intensity in a conductor of an electric current incorporating teachings of the present disclosure.

### DETAILED DESCRIPTION

The teachings of the present disclosure include apparatus for measuring a magnetic field of a conductor of an electric current, which can also be referred to as an electric conductor, wherein the magnetic field is measured without using a flux concentrator, having at least three magnetic field sensors, wherein the at least three magnetic field sensors are arranged on a circumference of an ellipse, wherein the ellipse is not a circle, wherein the at least three magnetic field sensors are arranged equidistantly along the circumference of the ellipse.

The flux concentrator which is not used may be in the form of a ferromagnetic core, in particular.

The circumference of the ellipse is a virtual or imaginary shape in this case. Equidistantly arranged means that the at least three magnetic field sensors, also referred to as the magnetic field sensors below, are distributed at equal spacings, that is to say uniformly spaced apart, along the circumference of the ellipse. This means that the at least three magnetic field sensors are evenly distributed around the circumference and circumferential sections of the same length lie between the at least three magnetic field sensors.

In some embodiments, an improved arrangement of the magnetic field sensors for measuring a magnetic field of a conductor of an electric current is selected, wherein the magnetic field is measured without using a flux concentrator. According to the prior art to date, a measurement of the magnetic field without using a flux concentrator is greatly dependent on an arrangement of the magnetic field sensors. This problem may be overcome by the arrangement described herein.

A flat, elliptical design that differs from a circular and/or cylinder-symmetrical arrangement of the magnetic field sensors saves space and, at the same time, makes it possible to control the individual magnetic field sensors more uniformly and thus a greater measurement range for the magnetic field and the electric current, which is advantageous, in particular, in flat conductors. An elliptical design which is suitable for different geometries of conductors and can therefore also be compared at the end of manufacturing on different busbars is also particularly favorable from a technical and logistical point of view.

The apparatus makes it possible to measure the current with very little dependence on a change in the conductor geometry. In addition, it is possible to manufacture busbars in a cost-effective and simple manner by avoiding screw points and associated losses in the busbars for introducing a cylindrical bar section, in particular a transformer bushing.

In some embodiments, the apparatus can also be used for electric conductors with a lower impedance and conductors with lower self-heating for the same losses, the magnetic field sensors can be easily compared, the magnetic field sensors can be easily started up, and the apparatus having the arrangement of magnetic field sensors, that is to say the arranged magnetic field sensors, can be used for a wide range of devices.

In order to obtain an elliptical sensor assembly which is as robust as possible with respect to the change in the conductor geometry after the comparison, in particular at the end of manufacturing, and can therefore be universally used, the magnetic field sensors may be distributed uniformly on the circumference of the ellipse, that is to say by means of even distribution around the circumference.

Since there is no analytical formula for calculating the magnetic field sensor positions evenly distributed around the circumference, they are numerically calculated. For this purpose, the circumference of the ellipse is divided into K sections. The K sections result in K corner points. The K corner points are numbered consecutively with a running index k. The subdivision into K corner points and therefore sections is carried out for the purpose of numerically calculating the length of the arc segment of the ellipse. Calculation is therefore carried out with a K corner instead of the ellipse. In this case, K is greater than 1000*N, in particular. However, only N, that is to say 7 for example, sensors are uniformly distributed over the K corner. In this case, the value of the running index k [0:K] is the number of the respective corner of the K corner. The magnetic field sensor with the number n is then situated at the corner with the number kₙ.

The k corner points have the coordinates xₖ and yₖ in an x-y coordinate system. The circumferential portion Uₖ of the sections is respectively calculated, where a is a longest half-axis of the ellipse and b is a shortest half-axis of the ellipse.

$${x}_{k} = a \cdot cos ( k \cdot \frac{360 °}{K} )$$

$${y}_{k} = b \cdot sin ( k \cdot \frac{360 °}{K} )$$

$$k = 0 … K ∈ ℕ$$

In this case: x₀=x_{K} and y₀=y_{K}. This “double assignment” is required for the following Uₖ formula.

Uₖ=\sqrt{(xₖ−Xₖ₋₁)²+(yₖ−yₖ₋₁)²}k=1 . . . K∈

[symbol]

The circumference of the ellipse therefore becomes:

U(k)=Σᵢ₌₁^{k}Uᵢ

This results in a one-to-one function U(k). The total circumference U of the ellipse corresponds to U=U(k=K).

It is possible to determine the sequence k(Uₙ) of the k corner points with the same circumferential spacing by using the inverse function k(U) and the sequence

$${U}_{n} = {U}_{0} + \frac{U}{N} \cdot n , n = 0 … N - 1 , n ∈ {ℕ}_{0} .$$

U₀ is referred to as an axial spacing and is described in more detail in the second part of the invention. The N magnetic field sensors (N=number of the at least three magnetic field sensors) can now be arranged on the ellipse with the circumferential spacing

$$\frac{U}{N} .$$

In some embodiments, the ellipse has a longest half-axis. The longest half-axis meets the ellipse at an ellipse apex. One of the at least three magnetic field sensors is arranged at an axial spacing from the ellipse apex. In this case, the axial spacing is measured along the circumference of the ellipse. According to the invention, the axial spacing is optimized to minimize a deviation of a result of the measurement of the magnetic field of the conductor of the electric current from a real value of the magnetic field of the conductor of the electric current.

In addition to the axial spacing of the one of the at least three magnetic field sensors, the further magnetic field sensors of the at least three magnetic field sensors have further axial spacings since the at least three magnetic field sensors are arranged equidistantly.

In some embodiments, the ellipse has a longest half-axis. The longest half-axis meets the ellipse at an ellipse apex. One of the at least three magnetic field sensors is arranged at an axial spacing from the ellipse apex. In this case, the axial spacing is measured along the circumference of the ellipse. In addition, a sensor spacing is defined by the circumference of the ellipse divided by a number of the at least three magnetic field sensors. This means that the sensor spacing indicates a spacing along the circumference of the ellipse between two adjacent magnetic field sensors of the at least three magnetic field sensors.

In some embodiments, the axial spacing:
is an eighth of the sensor spacing in the case of an odd number (N) of the at least three magnetic field sensors and
is a quarter of the sensor spacing in the case of an even number (N) of the at least three magnetic field sensors.

In some embodiments, in addition to the axial spacing of the one of the at least three magnetic field sensors, the further magnetic field sensors of the at least three magnetic field sensors have further axial spacings since the at least three magnetic field sensors are arranged equidistantly. If the at least three magnetic field sensors in an elliptical sensor assembly are distributed or arranged according to an even distribution around the circumference, this results in an optimum starting position, that is to say an optimum axial spacing from the ellipse apex, for a first magnetic field sensor, which results in a measurement error caused by a change in the width of the conductor being minimized. For this purpose, the axial spacing, that is to say circumferential segments U₀ on the ellipse, must be selected as follows with respect to the longest half-axis of the ellipse or with respect to the x axis of the coordinate system.

The axial spacing, that is to say circumferential segments U₀ on the ellipse, for an odd number (N) of magnetic field sensors, where an index of one of the magnetic field sensors is μ∈N₀, for the first magnetic field sensor is selected as μ equal to zero:

$${U}_{0} = \frac{U \cdot ( 2 μ + 1 )}{4 \cdot 2 \cdot N}$$

The axial spacing, that is to say circumferential segments U₀ on the ellipse, for an even number (N) of magnetic field sensors, where an index of one of the magnetic field sensors is μ∈N₀, for the first magnetic field sensor is selected as μ equal to zero:

$${U}_{0} = \frac{U ( 2 μ + 1 )}{4 \cdot N}$$

In addition to the axial spacing with μ equal to zero of the one of the at least three magnetic field sensors, the further magnetic field sensors of the at least three magnetic field sensors have further axial spacings since the at least three magnetic field sensors are arranged equidistantly to one another, measured along the circumference of the ellipse. The further axial spacings can be determined by means of μ equal to one to N, where N is the number of the at least three magnetic field sensors.

In some embodiments, the ellipse has a shortest half-axis. The longest half-axis does not exceed four times the length of the shortest half-axis. This minimizes a deviation of a result of the measurement of the magnetic field from a real value of the magnetic field. An experimental example is described in the description of the figures.

In some embodiments, the at least three magnetic field sensors each have a sensitivity axis. The at least three magnetic field sensors have the maximum sensitivity to a magnetic field oriented in the direction of the sensitivity axis. The sensitivity axis is oriented tangentially with respect to the ellipse. This means that the sensitivity axis runs parallel to magnetic field lines of the magnetic field. This has the advantage that the direction with the maximum sensitivity measures a maximum value of the magnetic field.

In some embodiments, there is an odd number (N) of the at least three magnetic field sensors. This may minimize a deviation of a result of the measurement of the magnetic field from a real value of the magnetic field. An experimental example is described in the description of the figures.

In some embodiments, the apparatus is designed to at least partially comprise the conductor of the electric current. This means that the conductor is arranged inside the ellipse.

Some examples include a current intensity determination unit, which can also be referred to as a determination unit, a measurement unit or a current transformer, for determining an electric current intensity in a conductor of an electric current. The current intensity determination unit has an apparatus as described herein, and a data processing unit, wherein the data processing unit is designed to determine the electric current intensity using, that is to say with the inclusion of, measurement results of a magnetic field strength of the magnetic field of the at least three magnetic field sensors.

Some examples include a method for determining an electric current intensity in a conductor of an electric current by means of a current intensity determination unit as described herein. In some embodiments, the method includes: placing the conductor of the electric current in an apparatus as described herein, determining measurement results of a magnetic field strength of the magnetic field by means of the apparatus, transmitting the measurement results to the data processing unit, and determining the electric current intensity in the conductor of the electric current by means of the data processing unit.

In all of embodiments shown in the figures, the magnetic field is measured without using a flux concentrator or a magnetic field sensor assembly without a flux concentrator is shown.

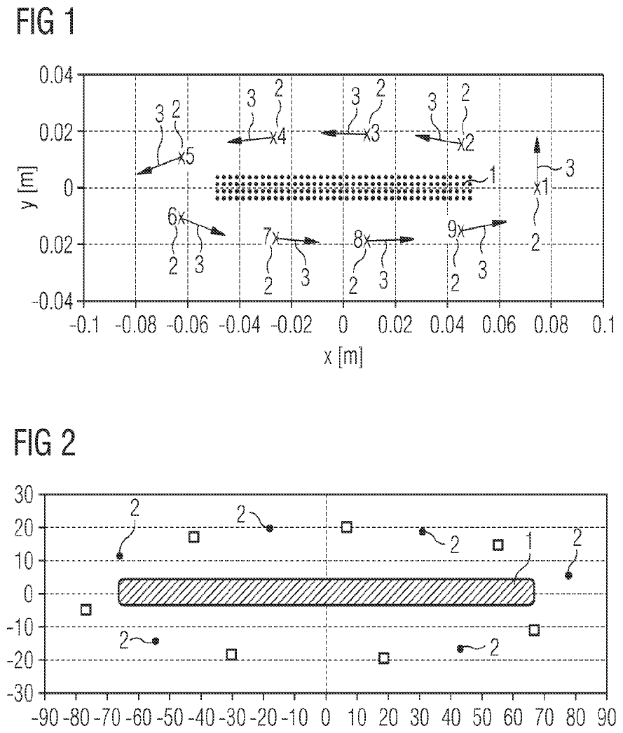

FIG. 1 shows nine magnetic field sensors 2 (number N=9, magnetic field sensors 2 ×1 to ×9) which are arranged equidistantly, which can also be referred to as evenly distributed around the circumference, along the circumference (U) of an ellipse in an x-y coordinate system (unit in meters m). This results in a sensor spacing, which can also be referred to as a circumferential spacing,

$$\frac{U}{N} = \frac{U}{9} .$$

The magnetic field sensors 2 are arranged without an offset angle from the x axis. The ellipse has a half-axis ratio of 4:1 (longest half-axis to shortest half-axis).

The sensitivity axes 3, which can also be referred to as sensitivity directions 3, of the magnetic field sensors 2 are represented by arrows in FIG. 1. The sensitivity axes 3 for the magnetic field sensors 2 are always oriented parallel to the tangent vector of the ellipse.

The dots in FIG. 1 represent electric currents which are used to approximate the electric current in the rectangular conductor 1. The conductor 1 with the rectangular cross section is approximated in the following calculations with a finite number of linear currents which have a spacing of 2.5 mm.

The circumference of the ellipse is divided into K sections. The K sections result in K corner points. The K corner points are numbered consecutively with a running index k. In this case, it should be noted that at least K>1000 N should apply in order to obtain reliable results. For the following calculations, K equal to 36,000 was used.

FIG. 2 shows seven magnetic field sensors 2 (N=7, represented by dots) which are arranged elliptically at an axial spacing from the ellipse apex. The scale of the coordinate system is given in any desired units. The half-axis ratio is 4:1 (longest half-axis to shortest half-axis) and the magnetic field sensors 2 are arranged in a manner evenly distributed around the circumference.

The axial spacing (circumferential segments U₀ on the ellipse) for an odd number (N=7) of magnetic field sensors 2, where the index μ is 0 to 6 for N=7 magnetic field sensors (μ∈N₀), for the first magnetic field sensor with μ equal to zero is determined by:

$${U}_{0} = \frac{U \cdot ( 2 μ + 1 )}{4 \cdot 2 \cdot N} = \frac{U}{4 \cdot 2 \cdot 7} = \frac{U}{56}$$

The optimum axial spacing U₀ of U/56, which can also be referred to as the initial circumference, minimizes a deviation of a result of the measurement of the magnetic field from a real value of the magnetic field. The result is thereby independent of the conductor width. U/56 corresponds to an angle of 3.89° in the x-y coordinate system. The individual circumferential segments U₀ to U₆ are delimited by squares in FIG. 2. A magnetic field sensor 2 is positioned in the center of each circumferential segment.

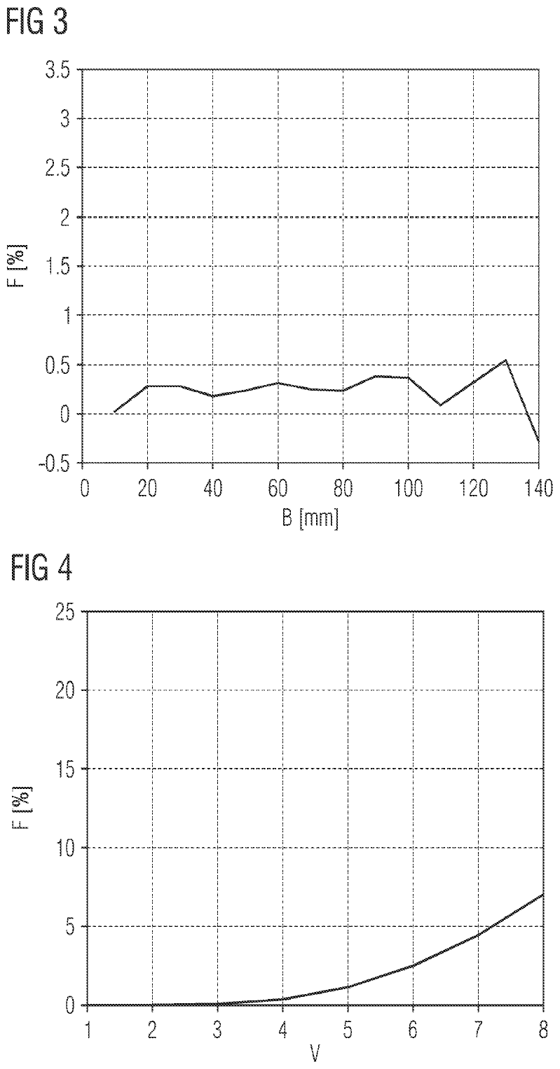

FIG. 3 shows experimentally determined measurement errors F on the basis of the conductor geometry, in particular the width B of a flat conductor during calibration, in particular comparison, on a linear conductor, wherein the magnetic field is measured without using a flux concentrator. The measurement error F, which can also be referred to as a relative sensitivity error F, is indicated in percent %. The width B of the flat conductor is indicated in millimeters mm.

The arrangement of the magnetic field sensors which is evenly distributed around the circumference makes it possible to achieve a very low dependence on the conductor geometry. Without weighting of the magnetic field sensors, the relative sensitivity error F remains below 0.4% as a result of the use of a flat conductor with a width B of 10 mm to 140 mm on the x axis and a fixed height of 10 mm during calibration with a linear conductor. Further conditions for creating the graph in FIG. 3 were a half-axis ratio of 4:1 (longest half-axis to shortest half-axis), a length of the longest half-axis of a=76 mm, a number of N=9 magnetic field sensors and an offset angle, that is to say an axial spacing, of 0°. Optimization of the axial spacing would further minimize the relative sensitivity error F.

FIG. 4 shows experimentally determined measurement errors F when the half-axis ratio V (longest half-axis to shortest half-axis) is changed during calibration with a linear conductor, wherein the magnetic field is measured without using a flux concentrator. The measurement error F, which can also be referred to as a relative sensitivity error F, during calibration with an linear conductor is indicated in percent %. The relative sensitivity error F depends greatly on the half-axis ratio V. This relationship is shown in FIG. 4. An evenly distributed sensor assembly of N=9 magnetic field sensors without an offset angle, in particular an axial spacing, with a longest half-axis of a=76 mm and a flat conductor with a rectangular cross section of 100 mm×10 mm was analyzed for different half-axis ratios V. The results are illustrated in FIG. 4. A larger half-axis ratio V results in a larger relative sensitivity error F. An even larger half-axis ratio V was not possible in the experiment since the magnetic field sensors would have no longer been able to be placed beside the flat conductor. Optimization of the axial spacing would further minimize the relative sensitivity error F.

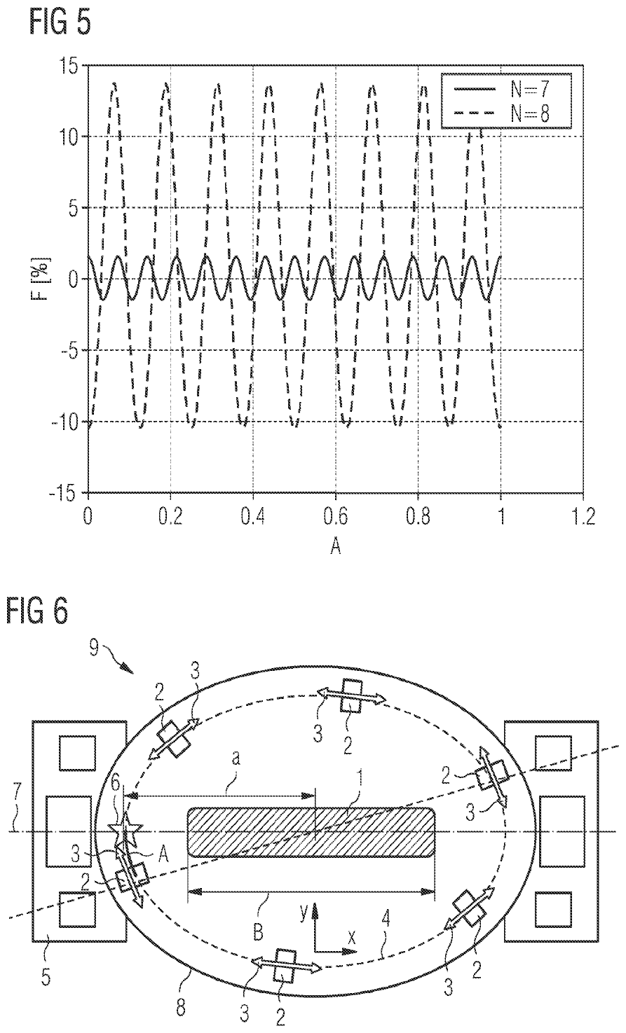

FIG. 5 shows experimentally determined measurement errors F during calibration with a linear conductor in the case of an odd number (N=7, solid graph) and an even number (N=8, dashed graph) of magnetic field sensors on the basis of the offset angle A or axial spacing A, wherein the magnetic field is measured without using a flux concentrator. The measurement error F, which can also be referred to as a relative sensitivity error F, is indicated in percent %. The relative sensitivity error F is represented for the measurement of a flat conductor with a width of 130 mm and an even distribution of the magnetic field sensors over the circumference on the basis of the offset angle A or axial spacing A. For this experiment, the flat conductor was approximated by means of 130 individual conductors which are uniformly arranged beside one another. The sensor array of the ellipse has a longest half-axis of 80 mm and a shortest half-axis of 20 mm. It can be seen in FIG. 5 that the maximum relative sensitivity errors F when using 7 magnetic field sensors (odd number) are smaller by a multiple than when using 8 magnetic field sensors (even number). An odd number of magnetic field sensors may be advantageous. Optimization of the axial spacing A minimizes the relative sensitivity error F.

FIG. 6 shows a current intensity determination unit 9 for determining an electric current intensity in a conductor 1 of an electric current, wherein the magnetic field is measured without using a flux concentrator. The conductor has the width B. The current intensity determination unit 9 has an apparatus 8 and a data processing unit 5.

The apparatus 8 is designed to measure a magnetic field of a conductor 1 of an electric current, wherein the magnetic field is measured without using a flux concentrator. The apparatus 8 at least partially comprises the conductor 1 of the electric current. The six magnetic field sensors are arranged on a circumference of an ellipse 4. The ellipse 4 is not a circle. The six magnetic field sensors 2 are arranged equidistantly along the circumference of the ellipse 4.

The magnetic field sensors each have a sensitivity axis 3. The magnetic field sensors 2 have the maximum sensitivity to a magnetic field oriented in the direction of the sensitivity axis 3. The sensitivity axis 3 is oriented tangentially with respect to the ellipse 4.

The ellipse 4 has a longest half-axis a. The longest half-axis a is on the main axis of symmetry 7. The longest half-axis a meets the ellipse 4 at an ellipse apex 6. The ellipse apex 6 is indicated by a star in FIG. 6. One of the at least three magnetic field sensors 2 is arranged at an axial spacing A from the ellipse apex 6 along the ellipse. In this case, the axial spacing A is measured along the circumference of the ellipse 4.

The axial spacing A is optimized to minimize a deviation of a result of the measurement of the magnetic field of the conductor 1 from a real value of the magnetic field of the conductor 1, wherein the magnetic field is measured without using a flux concentrator. This can be achieved, in particular, by virtue of a sensor spacing being defined by the circumference of the ellipse 4 divided by a number (N) of the magnetic field sensors 2, wherein the axial spacing A: is an eighth of the sensor spacing in the case of an odd number (N) of the magnetic field sensors 2 and is a quarter of the sensor spacing in the case of an even number (N) of the magnetic field sensors 2.

The data processing unit 5 is designed to determine the electric current intensity using measurement results from the six magnetic field sensors 2. The six magnetic field sensors 2 may measure, in particular, a magnetic field strength of the magnetic field.

Although the teachings herein have been described and illustrated more specifically in detail by means of the exemplary embodiments, the teachings herein are not restricted by the disclosed examples and other variations can be derived therefrom by a person skilled in the art without departing from the scope of protection of the disclosure.

### LIST OF REFERENCE SIGNS

1 Conductor of an electric current
2 Magnetic field sensor
3 Sensitivity axis
4 Ellipse
5 Data processing unit
6 Ellipse apex
7 Main axis of symmetry
8 Apparatus
9 Current intensity determination unit
a Longest half-axis
A Axial spacing
N Number of magnetic field sensors 2

What is claimed is:

1. An apparatus for measuring a magnetic field of a conductor of an electric current, the apparatus comprising:
magnetic field sensors arranged on a circumference of a non-circular ellipse;
wherein the three magnetic field sensors are arranged equidistantly along the circumference of the ellipse; and
the magnetic field is measured without using a flux concentrator.

2. The apparatus as claimed in claim 1,
wherein:
the ellipse has a longest half axis the circumference at an ellipse apex;
one of the three magnetic field sensors is arranged at an axial spacing from the ellipse apex;
the axial spacing is optimized to minimize a deviation of a result of the measurement of the magnetic field of the conductor of the electric current from a real value of the magnetic field of the conductor of the electric current.

3. The apparatus as claimed in claim 1,
wherein:
there are three or more magnetic field sensors;
the ellipse has a longest half axis circumference of the ellipse at an ellipse apex;
one of the at three or more magnetic field sensors is arranged at an axial spacing from the ellipse apex;
a sensor spacing is defined by the circumference of the ellipse divided by a count of the three or more magnetic field sensors;
the axial spacing is an eighth of the sensor spacing in the case of an odd number of the three or more magnetic field sensors, or a quarter of the sensor spacing in the case of an even number of the three or more magnetic field sensors.

4. The apparatus as claimed in claim 2,
wherein:
the ellipse has a shortest half-axis; and
the longest half axis does not exceed four times the length of the shortest half-axis.

5. The apparatus as claimed in claim 1,
wherein:
the three magnetic field sensors each have a sensitivity axis defined by a respective maximum sensitivity to a magnetic field oriented in the direction of the sensitivity axis; and
the sensitivity axis is oriented tangentially with respect to the ellipse.

6. The apparatus as claimed in claim 1, wherein:
there are more than three magnetic field sensors; and
there is an odd number of the more than three magnetic field sensors.

7. The apparatus as claimed in claim 1, wherein the apparatus at least partially makes up the conductor of the electric current.

8. A current intensity determination unit for determining an electric current intensity in a conductor of an electric current, the unit comprising:
a data processing unit;
three magnetic field seniors arranged on a circumference of a non-circular ellipse;
wherein the three magnetic field sensors are arranged equidistantly along the circumference of the ellipse;
the magnetic field is measured without using a flux concentrator; and
the data processing unit determines the electric current intensity using measurement results from the three magnetic field sensors.

9. A method for determining an electric current intensity in a conductor W of an electric current using a current intensity determination unit with a data processing unit and three magnetic field sensors arranged on a circumference of a non-circular ellipse, wherein the three magnetic field sensors are arranged equidistantly measured without using a flux concentrator the method comprising:
placing the conductor of the electric current in the apparatus;
determining measurement results of a magnetic field strength of the magnetic field using the apparatus;
transmitting the measurement results to the data processing unit; and
determining the electric current intensity in the conductor of the electric current using the data processing unit.
